(19) United States
(12) Patent Application Publication
(10) Pub. No.: US 2024/0167195 A1
(43) Pub. Date: May 23, 2024

(54) LAYER-BY-LAYER VAN DER WAALS EPITAXIAL GROWTH OF WAFER-SCALE MOS2 CONTINUOUS FILMS

(71) Applicant: INSTITUTE OF PHYSICS, CHINESE ACADEMY OF SCIENCES, Beijing (CN)

(72) Inventors: Qinqin WANG, Beijing (CN); Guangyu ZHANG, Beijing (CN); Rong YANG, Beijing (CN); Dongxia SHI, Beijing (CN); Gang SUN, Beijing (CN)

(21) Appl. No.: 18/549,172

(22) PCT Filed: Mar. 19, 2021
(86) PCT No.: PCT/CN2021/081921

§ 371 Date: Sep. 6, 2023

(51) Int. Cl. C30B 25/10; C30B 29/46; H01L 21/02

(52) U.S. Cl. CPC C30B 25/10; C30B 29/46; H01L 21/02568; H01L 21/0262; H01L 21/02378; H01L 21/02389; H01L 21/0242

(57) ABSTRACT

A MoS₂ continuous film on substrate, characterized in that, the domain size of the MoS₂ continuous film is larger than 100 μm (layer number=1), 10 μm (layer number≥2), respectively. High-quality MoS₂ films of the present invention with different layer numbers (layer number≥2) on a substrate. The films can be continuous over large area (e.g., 4 in. wafer-scale). The films can be made based on chemical vapor deposition method. The films can be used in electrical and electronic devices (e.g., high performance thin-film transistors, logic devices, sensors).

### TECHNICAL FIELD

The present invention disclosure related to growth of large-area MoS₂ continuous films with different layer numbers. More specifically, the present invention disclosure relates to 4-inch high quality MoS₂ multilayer continuous films through layer-by-layer van der Waals epitaxial growth.

### BACKGROUND

MoS₂, a representative two-dimensional material, has shown great potential in large-scale integrated circuits. Many efforts have been devoted to produce high quality MoS₂. Up to now, wafer-scale high-quality monolayer MoS₂ has been achieved. In fact, multilayer MoS₂ is more suitable for high performance electronic devices due to the higher density of states. However, wafer-scale layer-controlled MoS₂ with spatial homogeneity and high quality still remains a great challenge.

To date, existing methods (such as ALD and sulphurization of metal or metal compounds) for produce large-area bilayer or multilayer (layer number ≥3) usually suffer from low crystallinity, and small domain size (typically smaller than 0.1 μm), as a result, the achieved material usually shows poor electrical performance. For example, the sulphurization of metal or metal compounds only provides average thickness-controlled of the resulting films, leading to a bad continuity and inhomogeneity. Chemical vapour deposition (CVD) is an effective way for growth monolayer large-area high quality two-dimensional materials films on various substrate, however, the bilayer growth is still very challenging due to the self-limiting growth process which usually obtain monolayer films. For MoS₂, highly crystalline ML MoS₂ flakes has been achieved by CVD, however, usually produce different layer ranging from monolayer to multilayer in a batch. It is still very challenging to produce bilayer and multilayer continuous MoS₂ films with highly crystalline in a controlled manner. Up to now, large-scale uniform and continuous multilayer MoS₂ films with large domain size (each layer ≥10 μm) is still unavailable.

Therefore, there is a demand for a new method to produce layer-controlled high quality MoS₂.

### SUMMARY OF THE INVENTION

The present invention includes epitaxy MoS₂ on a substrate (e.g., sapphire, Si/SiO₂ substrate, mica, SiC, etc.) with controlled layer numbers. The achieved films show high crystallinity, and the domain size is larger than 100 μm (layer number=1), 10 μm (layer number ≥2), respectively. In one example, a method can achieve 4-inch wafer-scale multilayer MoS₂ continuous films. The multilayer films growth shows good layer controlled. The method includes use a low growth temperature to grow monolayer and a relatively high temperature to grow second layer.

The first aspect of the present invention provides a MoS₂ continuous film on substrate, characterized in that, the domain size of the MoS₂ continuous film is larger than 10 μm;
wherein the MoS₂ continuous film has one layer or more layers.

According to the MoS₂ continuous film of the first aspect, wherein the substrate is one or more selected from of the group consisting of sapphire, Si/SiO₂ substrate, mica, SiC, BN, SrTiO₃; preferably, the substrate is sapphire.

According to the MoS₂ continuous film of the first aspect, wherein the MoS₂ film has one layer, and the domain size of the MoS₂ film is larger than 100 μm; and/or the average field-effect mobility is 70˜80 cm²/Vs.

According to the MoS₂ continuous film of the first aspect, wherein the MoS₂ film has two layers, and the average field-effect mobility is 110˜120 cm²/Vs; and/or
the MoS₂ film has three layers, and the average field-effect mobility is 120˜140 cm²/Vs

The second aspect of the present invention provides a method of preparing the MoS₂ continuous film according to the first aspect, the method comprising the following steps:
(1) sublimating of sulfur and MoO₃;
(2) transferring the S and MoO₃ species by different carrier gas;
(3) proceeding reactions of sulfur and MoO₃ to produce MoS₂ species;
(4) forming monolayer MoS₂ on the substrate; and
(5) increasing the growth temperature and form multilayer MoS₂ on the substrate.

According to the method of the second aspect, wherein in step (2), the carrier gas of S is one or more selected from of the group consisting of Ar or N₂; and/or
the carrier gas of MoO₃ is one or more selected from of the group consisting of Ar, N₂, O₂.

According to the method of the second aspect, wherein in step (3), the reaction temperature is 120˜140° C. for S source and 540° C.˜570° C. for MoO₃, respectively; and/or
in step (4), the growth temperature is 760-930° C.

According to the method of the second aspect, wherein in step (5), the growth temperature is 820-970° C.

According to the method of the second aspect, wherein in step (5), the chamber pressure is 0.8˜1.3 torr.; preferably, the chamber pressure is 1 torr.

According to the method of the second aspect, wherein when the MoS₂ film has two or more layers, form the second layer MoS₂ after the first layer is formed on the substrate 95% or greater covered on the substrate.

The third aspect of the present invention provides an electrical and/or electronic device, the electronic device comprises: the MoS₂ continuous film according to the first aspect; and/or the MoS₂ continuous film prepared according to the method of the second aspect;
preferably, the electrical and/or electronic device is one or more selected from of thin-film transistors, logic devices, sensors, memory devices, wearable electronics, neuromorphic computing devices, brain-inspired electronics, complex electronic circuits or systems.

In an aspect, the present invention provides a method to epitaxy monolayer to multilayer high quality MoS₂. The methods are based on a 4-inch multisource chemical vapour deposition (CVD) system. The methods are based on a layer-controlled growth mode.

In an example, the achieved 4-inch bilayer MoS₂ continuous films shows great spatial homogeneity. There are very little monolayer and trilayer areas, suggesting our growth is of great layer-controlled. And there are only two stacking orders in our bilayer MoS₂ continuous films, no other rotation angels and twisted stacking arrangement were observed, indicating the high quality of the achieved films.

In another example, the achieved 4-inch trilayer MoS₂ continuous films exhibit desirable spatial uniformity and electrical performance.

In an aspect, the achieved continuous can be used in but not limit to logic circuits, memory devices, thin film transistors.

Usually, for synthesizing multilayer continuous MoS₂ films, the difficulty is to achieve a planar growth in a controlled manner for each layer, for instance, the sulphurization of metal or metal compounds methods usually produce a mixture of monolayer, multilayer and no-growth area.

In this invention, we use a two-stage CVD methods to grow the multilayer continuous MoS₂ films through a layer-by-layer van der Waals epitaxial process. We first use a low growth temperature to grow monolayer and then a relatively high temperature to grow second layer, this high temperature both for the substrate and source can facilitate the second layer formed on the first layer. Besides, we use a multisource CVD system to guarantee a homogenous source supply thus can promote the homogeneity of the multilayer continuous films.

### BRIEF DESCRIPTION OF THE DRAWINGS

A more detailed description of the embodiments of this application is given in conjunction with the appended drawings. In the drawings:

FIG. 1 shows the schematic diagram of the 4 in. multisource CVD setup.

FIG. 2 shows the 4 in. wafer-scale MoS₂ on sapphire.

FIG. 3 is the optical images of the as-grown MoS₂ with different layers; wherein FIG. 3a shows the optical image of the achieved monolayer films (the upper left corner is an intentional scratch.); FIG. 3b shows the monolayer MoS₂ with 60% second layer domains on it (˜1.6 L MoS₂), the epitaxy second layer has a grain size about 10 μm with hexagon shapes; FIG. 3c shows the continuous bilayer MoS₂ films; FIG. 3d shows a continuous trilayer MoS₂ films with some little multilayer grain on it; FIG. 3e shows a continuous trilayer MoS₂ films with some little multilayer grain on it.

FIG. 4 is the Raman spectral of the as-grown MoS₂ with different layers (layer number =1,2,3).

FIG. 5 is the photoluminescence (PL) spectral of the as-grown MoS₂ with different layers (layer number=1,2,3).

FIG. 6 is the Raman spectra for the as-grown MoS₂ with different layers (layer number=1,2,3), respectively, taken at different locations at the wafer, wherein FIG. 6A corresponds to monolayer MoS₂, FIG. 6B corresponds to bilayer MoS₂, and FIG. 6C corresponds to trilayer MoS₂.

FIG. 7 is the cross-sectional TEM images of the as-grown MoS₂ with different layers (layer number=1,2,3), wherein FIG. 7A corresponds to monolayer MoS₂, FIG. 7B corresponds to bilayer MoS₂, and FIG. 7C corresponds to trilayer MoS₂.

FIG. 8 is the typical selected area electron diffraction (SAED) pattern of the as-grown MoS₂ with different layers (layer number=1,2,3).

### DETAILED DESCRIPTION OF THE EMBODIMENTS

The present invention is further described in the appended drawings and specific embodiments below.

This application provides a method for forming a wafer-scale MoS₂ continuous films with different layers. Specifically, the chemical gas phase is assisted by oxygen in a multisource system to epitaxial growth of wafer-scale MoS₂ continuous films with different layers. The wafer-scale continuous multilayer MoS₂ film is obtained on the substrate (e.g., sapphire, Si/SiO₂ substrate, mica, SiC, etc.) is highly spatially homogeneous and electrically consistent. The achieved multilayer MoS₂ continuous films show excellent electrical performance, including an average field-effect mobility is ˜70 cm²/Vs for monolayer and >100 cm²/Vs for bilayer at room temperature, ˜130 cm²/Vs for trilayer films.

The following examples further illustrate the present disclosure and are not intended to limit the scope of the invention.

### Example 1

The epitaxial growth of the multilayer MoS₂ continuous films with different layers on a substrate is described. Sulfur powder (S), molybdenum trioxide (MoO₃), and a 4 in. sapphire substrate were placed in Zone I, II, III. These three temperature zones (Zone I, II, III) are successively distributed along the gas flow direction, respectively. Vacuum was draw below 0.01 torr and then 280 sccm Ar and 10 sccm O₂ were introduced to the chamber, the first stage is to grow continuous monolayer MoS₂ films on sapphire substrate and it takes about 30 minutes, the first stage under a relatively low growth temperature of ˜900° C., and the S and MoO₃ was warmed to 120° C. and 540° C., respectively. After the monolayer continuous films is fully covered the substrate, we increase the substrate temperature to ˜940° C. and the temperature of MoO₃ to 560° C. to grow the second layer since a higher growth temperature is beneficial for vertically growth.

Sulfur powder (S), molybdenum trioxide (MoO₃), and a 4 in. Si/SiO₂ substrate were placed in Zone I, II, III, respectively. Vacuum was draw below 0.01 torr and then 280 sccm Ar and 5 sccm O₂ were introduced to the chamber, the first stage takes about 30 minutes under a relatively low growth temperature of ˜760° C., and the S and MoO₃ was warmed to 120° C. and 540° C., respectively. After the monolayer continuous films is fully covered the substrate, we increase the substrate temperature to ˜820° C. and the temperature of MoO₃ to 560° C. to grow the second layer.

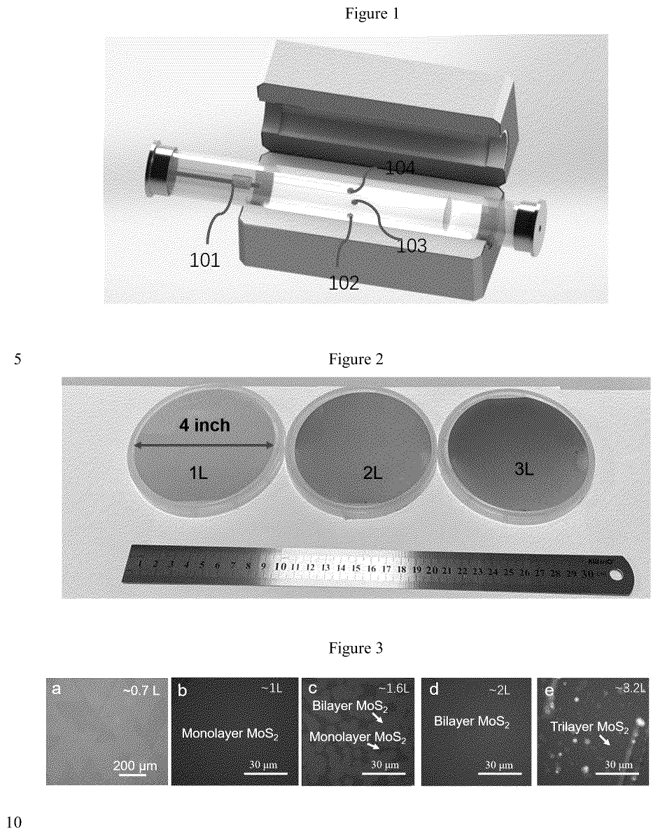

FIG. 1 shows the multisource CVD system, in this special designed system, there are more than one minitube to load the MoO₃ source, the minitube for loading MoO₃ source can reach up to six and is evenly distributed of the central minitube which used for loading S source, this is the key to achieved high uniform multilayer MoS₂. The tube 101 loaded S source, and the minitube 102, 103, 104 loaded the MoO₃ source. Sulfur powder (S), molybdenum trioxide (MoO₃), and a 4 in. sapphire substrate were placed in Zone I, II, III, respectively. Vacuum was draw below 0.01 torr and then 280 sccm Ar and 10 sccm O₂ were introduced to the chamber, the first stage takes about 30 minutes under a relatively low growth temperature of ˜910° C., and the S and MoO₃ was warmed to 120° C. and 540° C., respectively. After the monolayer continuous films is fully covered the substrate, we increase the substrate temperature to ˜950° C. and the temperature of MoO₃ to 560° C. to grow the second layer. After 20 minutes, we further increase the temperature of MoO₃ to 570° C. to grow the third layer. And the substrate temperature keep at ˜950° C. After about 20 minutes, we can achieve wafer-scale trilayer continuous MoS₂ films. Followed by a continuous growth at this condition, we can achieve a multilayer continuous films (layer number ≥4).

FIG. 2 shows the photo images of 4 in. monolayer (1 L), bilayer (2 L), and trilayer (3 L) MoS₂ wafer, respectively. We grew the first layer MoS₂ at ˜900° C., after ˜30 min, the first layer is fully covered on the substrate, we increase up to ˜940° C. to grow the second layer. FIG. 3a shows optical microscope images of monolayer MoS₂ grown on sapphire for 20 min, and we can see the domain size of the monolayer films is greater than 100 μm on average. FIG. 3b shows the optical image of the achieved monolayer films (the upper left corner is an intentional scratch.), the second layer are barely seen. As we can see in FIG. 3c, monolayer MoS₂ with 60% second layer domains on it (˜1.6 L MoS₂), the epitaxy second layer has a grain size about 10 μm with hexagon shapes, which is much bigger than the reported bilayer continuous films (typically with domain sizes smaller than 0.1 μm). FIG. 3d shows the continuous bilayer MoS₂ films, there are very little monolayer and trilayer areas, suggesting our growth is of great layer-controlled. FIG. 3e shows a continuous trilayer MoS₂ films with some little multilayer grain on it.

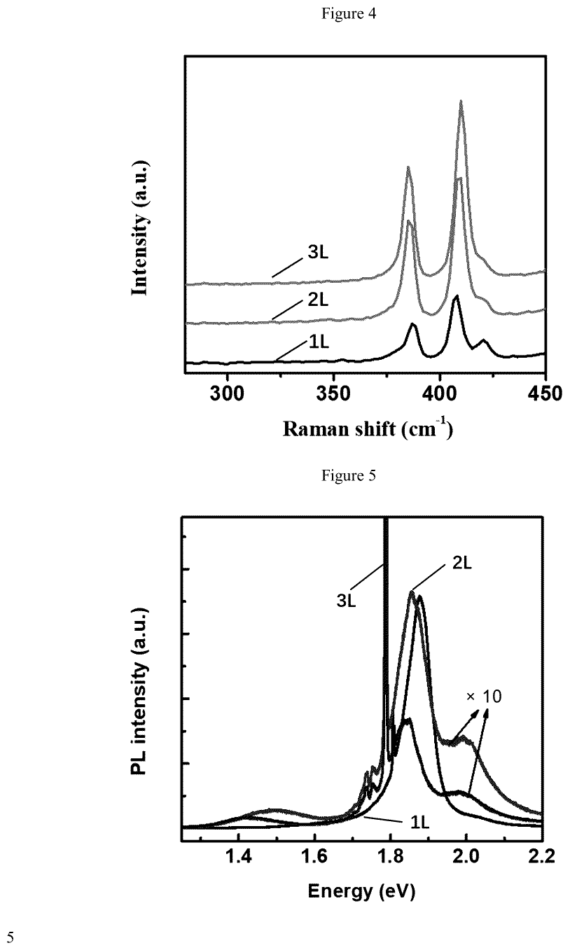

We characterized the achieved MoS₂ thin films using Raman and photoluminescence (PL) spectroscopy. FIG. 4 shows the Raman spectra of the achieved MoS₂ continuous films with different layers on 4 in. sapphire substrate. For 1 L MoS₂ films, the peak frequencies difference (Δ) between the E_{2g} and A_{1g} vibration modes is about ˜20 cm⁻¹. Compare with the IL MoS₂ films, the spectra of 2 L has a bigger Δ and higher peak intensity. And the spectra of 3 L has a bigger Δ and higher peak intensity than 2 L. FIG. 5 shows the PL spectra of the achieved MoS₂ continuous films with different layers on 4 in. sapphire substrate. we can see the IL MoS₂ has a strong PL peak at ˜1.9 eV while the 2 L and 3 L films has a greatly suppressed peak intensity due to the interlayer coupling lead the direct band gap to an indirect one, we also observe the indirect bandgap peaks at ˜1.50 and 1.42 eV for 2 L and 3 L MoS₂ respectively.

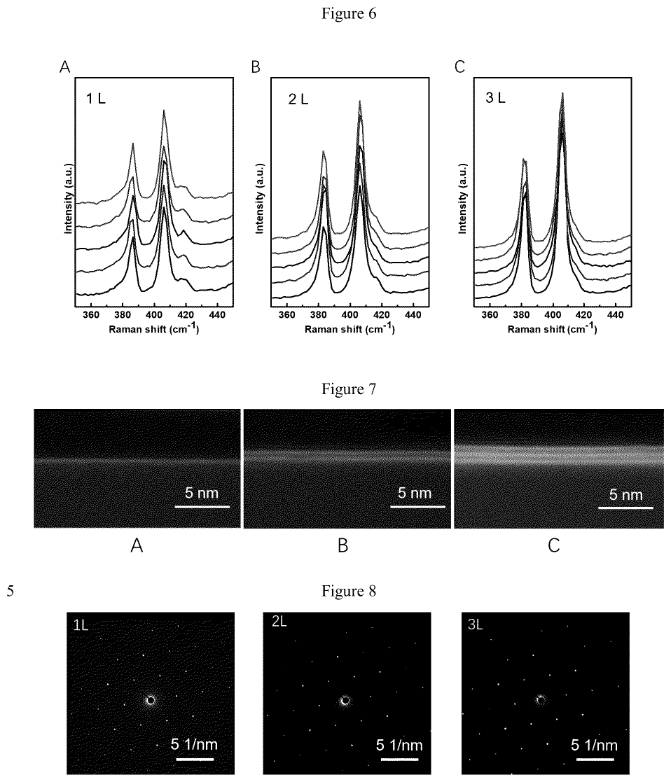

FIG. 6A-C shows the Raman spectra collected from five different areas of the 1 L, 2 L and 3 L MoS₂ continuous films, respectively. We can see these measured spectra nearly have the same peak position regardless of the different areas in a certain layer MoS₂ continuous films, which indicates the high uniformity of our achieved MoS₂ continuous films. FIG. 7 show the cross-section transmission electron microscope (TEM) images of as-grown IL, 2 L and 3 L MoS₂ continuous films. From these images we can see the achieved multilayer MoS₂ is of great layer-controlled, they are uniform in every layer.

The as-grown IL, 2 L and 3 L MoS₂ continuous films exhibit excellent crystalline quality. FIG. 8 shows the selected-area electron diffraction (SAED) pattern of the achieved films, both of them exhibiting only one set of hexagonal diffraction spots, indicating there are only two stacking orders in our films, no other rotation angels and twisted stacking arrangement.

Heretofore, the technical solution of the present invention has been described with reference to the preferred embodiments shown in the drawings, but it is easy for the person skilled in the art to understand that the protection scope of the present invention is obviously not limited to these specific embodiments. On the premise of not deviating from the principle of the present invention, a person skilled in the art can make equivalent changes or substitutions to relevant technical features, and the technical solutions after these changes or substitutions will fall within the protection scope of the present invention.

1. A MoS₂ continuous film on substrate, characterized in that, the domain size of the MoS₂ continuous film is larger than 10 μm; wherein the MoS₂ continuous film has one layer or more layers.

2. The MoS₂ continuous film according to claim 1, characterized in that, the substrate is one or more selected from of the group consisting of sapphire, Si/SiO₂ substrate, mica, SiC, BN, SrTiO₃; preferably, the substrate is sapphire.

3. The MoS₂ continuous film according to claim 1, characterized in that, the MoS₂ film has one layer, and the domain size of the MoS₂ film is larger than 100 μm; and/or the average field-effect mobility is 70˜80 cm²/Vs.

4. The MoS₂ continuous film according to claim 1, characterized in that, the MoS₂ film has two layers, and the average field-effect mobility is 110˜120 cm²/Vs; and/or
the MoS₂ film has three layers, and the average field-effect mobility is 120˜140 cm²/Vs.

5. A method of preparing the MoS₂ continuous film according to claim 1, characterized in that, the method comprising the following steps:
(1) sublimating of sulfur and MoO₃;
(2) transferring the S and MoO₃ species by different carrier gas;
(3) proceeding reactions of sulfur and MoO₃ to produce MoS₂ species;
(4) forming monolayer MoS₂ on the substrate; and
(5) increasing the growth temperature and form multilayer MoS₂ on the substrate.

6. The method according to claim 5, characterized in that, in the step, of transferring the S and MoO₃ species by different carrier gas, the carrier gas of S is one or more selected from of the group consisting of Ar or N₂; and/or the carrier gas of MoO₃ is one or more selected from of the group consisting of Ar, N₂, O₂.

7. The method according to claim 5 characterized in that, in the step of proceeding reactions of sulfur and MoO₃ to produce MoS₂ to species step (3), the reaction temperature is 120 ˜140° C. for S source and 540° C.˜570° C. for MoO₃, respectively; and/or in the step of forming monolayer MoS₂ on the substrate in step (4), the growth temperature is 760˜930° C.

8. The method according to claim 5, characterized in that, the step of increasing the growth temperature and form multilayer MoS2 on the substrate, the growth temperature is 820˜970° C.

9. The method according to claim 5, characterized in that, in the step of increasing the growth temperature and form multilayer MoS2 on the substrate, the chamber pressure is 0.8˜1.3 torr; preferably, the chamber pressure is 1 torr.

10. The method according to claim 5, characterized in that, when the MoS₂ film has two or more layers, form the second layer MoS₂ after the first layer is formed on the substrate 95% or greater covered on the substrate.

11. An electronic device, comprising a MoS₂ continuous film, wherein the domain size of the MoS2, continuous film is larger than 10 μm; wherein the domain size of the MoS2 continuous film is larger than 10 μm; wherein the MoS2 continuous film has one later or more layers according to claim 1, and/or the MoS₂ continuous film prepared according to the method

12. The electronic device according to claim 11, the electronic device is one or more selected from thin-film transistors, logic devices, sensors, memory devices, wearable electronics, neuromorphic computing devices, brain-inspired electronics, complex electronic circuits or systems.
